(19) United States
(12) Patent Application Publication
(10) Pub. No.: US 2012/0074078 A1
(43) Pub. Date: Mar. 29, 2012

(54) MOUNTING APPARATUS FOR DATA STORAGE DEVICE

(75) Inventors: ZHEN-XING YE, Shenzhen City (CN); HUNG-CHOU CHAN, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/916,629

(22) Filed: Oct. 31, 2010

(30) Foreign Application Priority Data
Sep. 23, 2010 (CN) 201010289266.4

(51) Int. Cl. H05K 7/14

(52) U.S. Cl. 211/26

(57) ABSTRACT

A mounting apparatus for data storage devices includes a first bracket and a second bracket pivotably attached to the first bracket end-to-end. The first bracket includes a first connection portion and a second connection portion. The second bracket includes a connection post received in the first connection portion and the second connection portion.

### BACKGROUND

1. Technical Field

The present disclosure relates to device mounting, and particularly, to a mounting apparatus for data storage devices.

2. Description of Related Art

An electronic device, such as a computer or a server, usually includes data storage devices, such as hard disk drives, compact disk read-only memory (CD-ROM) drives, and digital video disk (DVD) drives. These devices will be attached on brackets. However, the data storage devices may be placed in a front-to-back direction or an up and down direction. Conventional brackets for the front-to-back direction and the up and down direction are punched in different processes, which is time consuming and costly.

Therefore, a mounting apparatus is desired to overcome the limitations described.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an exploded, isometric view of an embodiment of a mounting apparatus for data storage devices, the mounting apparatus includes a first bracket and a second bracket.

FIG. 2 is an exploded, isometric view of FIG. 1, but viewed from another aspect.

FIG. 3 is an enlarged view of a first fixed portion of the first bracket and a second fixed portion of the second bracket of FIG. 1.

FIG. 4 is assembled, isometric view of FIG. 1, showing the first bracket and the second bracket placed in a front-to-back direction.

FIG. 5 is assembled, isometric view of FIG. 1, showing the first bracket and the second bracket placed in an up and down direction.

### DETAILED DESCRIPTION

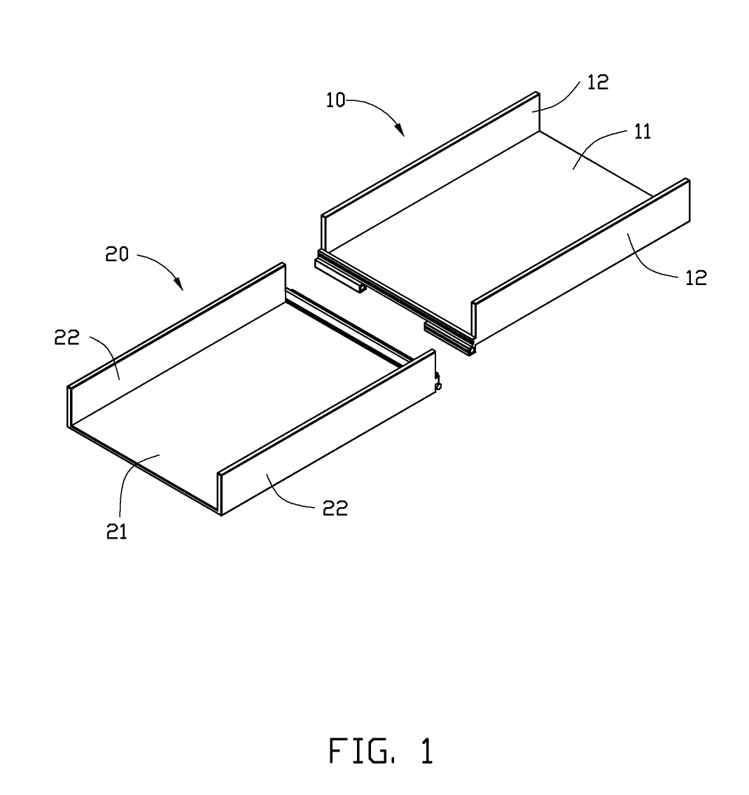

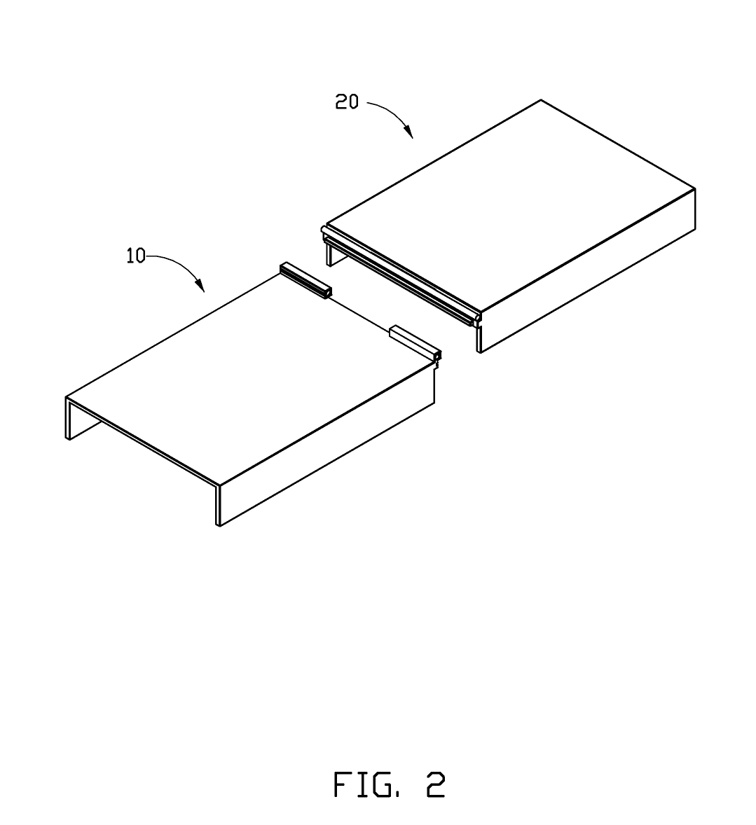

Referring to FIGS. 1-2, an exemplary embodiment of a mounting apparatus is provided for mounting two data storage devices (not shown), such as hard disk drives, to an electronic device (not shown). The mounting apparatus includes a first bracket 10 and a second bracket 20 pivotably attached to the first bracket 10 end-to-end.

The first bracket 10 includes a first bottom plate 11 and two first side plates 12 extending up from two opposite edges of the bottom plate 11, cooperatively defining a receiving space for receiving one of the two data storage devices therein. The second bracket 20 includes a second bottom plate 21 and two second side plates 22 extending up from two opposite edges of the bottom plate 21, cooperatively defining a receiving space for receiving the other data storage device therein. The first bracket 10 and the second bracket 20 are substantially U-shaped. The two data storage devices can be secured respectively to the first bracket 10 and the second bracket 20 by connecting members (not shown). The connecting members, well known in the fields related to the invention, are not described in detail here.

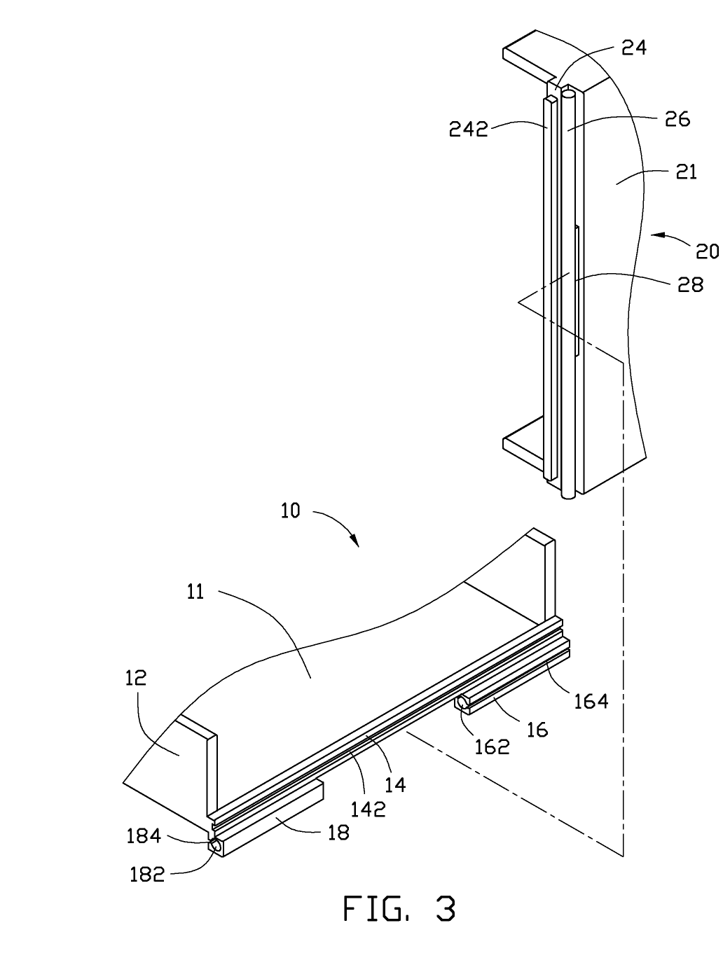

Referring to FIG. 3, a first fixed portion 14 extends outward from an end of the first bottom plate 11 of the first bracket 10. Two ends of the first fixed portion 14 connect the two first side plates 12 respectively. A recess 142 is defined in outside of the first fixed portion 14. In the illustrated embodiment, the recess 142 is bar-shaped. The first bottom plate 11 includes a first connection portion 16 and a second connection portion 18. The first connection portion 16 extends from a right edge of the first bottom plate 11 and away from the two first side plates 12. The second connection portion 18 extends from a left edge of the first bottom plate 11 and away from the two first side plates 12. The first connection portion 16 includes a first connection recess 162 defined therein and a first opening 164 defined in an outer surface of the first connection portion 16. The first connection recess 162 communicates with the second portion 164. The second connection portion 18 includes a second connection recess 182 defined therein and a second opening 184 defined in an outer surface of the second connection portion 18. The second connection recess 182 communicates with the second opening 184. A direction of the first opening 164 and the second opening 184 face away from each other. The first connection portion 16 and the second connection portion 18 may be made of resilient material. In the illustrated embodiment, the resilient material may be rubber or silicone.

A second fixed portion 24 extends outward from an end of the second bottom plate 21 of the second bracket 20. The second fixed portion 24 includes a bar 242 extending outward therefrom. A connection post 26 is placed adjacent the second fixed portion 24. The connection post 26 includes a third connection portion 28 defined on a middle thereof. The connection post 26 fixes to the second bottom plate 21 by the third connection portion 28.

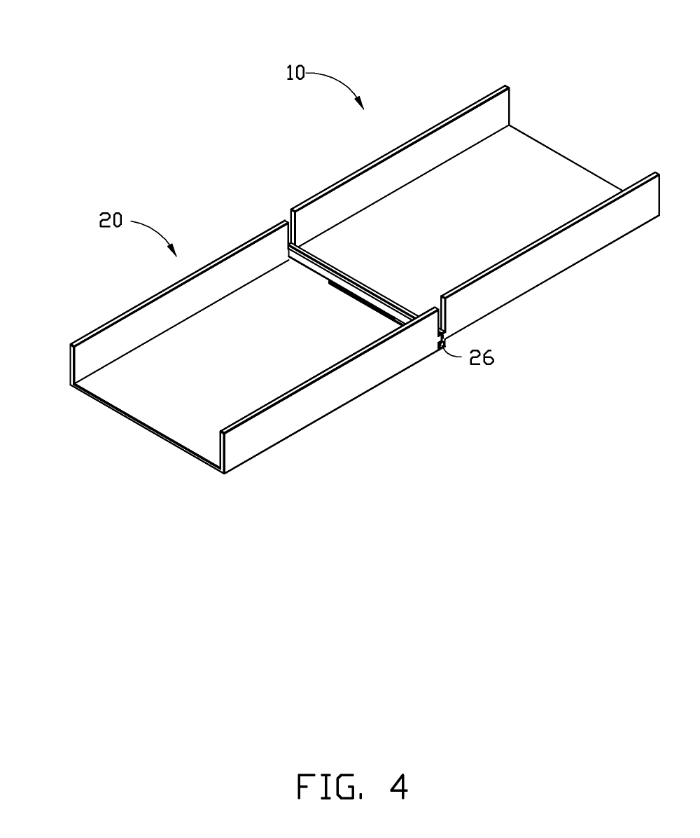

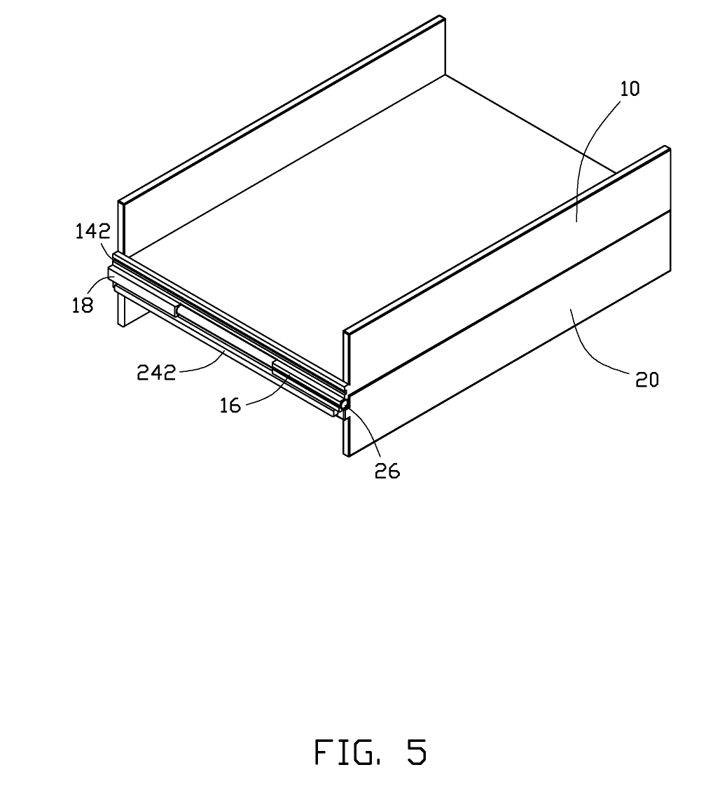

Referring to FIGS. 4-5, in assembly of the second bracket 20 to the first bracket 10, two ends of the connection post 26 are respectively received in the first connection recess 162 of the first connection portion 16 and the second connection recess 182 of the second connection portion 18 through an elastic deformation of the first opening 164 and the second opening 184.

In use, when the two data storage devices need be placed in a front-to-back direction, the bar 242 of the second bracket 20 is received in the recess 142 of the first bracket 10. Accordingly, the first bracket 10 and the second bracket 20 are placed in a front-to-back direction (FIG. 4). When the two data storage devices need be placed in an up and down direction, the second bracket 20 is rotated relative to the first bracket 10. Therefore, the first bracket 10 and the second bracket 20 are placed in an up and down direction (FIG. 5).

While the disclosure has been described by way of example and in terms of preferred embodiment, it is to be understood that the invention is not limited thereto. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A mounting apparatus for data storage devices, the mounting apparatus comprising:
a first bracket comprising a first connection portion and a second connection portion; and
a second bracket pivotably attached to the first bracket end-to-end, wherein the second bracket comprises a connection post received in the first connection portion and the second connection portion.

2. The mounting apparatus of claim 1, wherein the first connection portion comprises a first connection recess defined therein and a first opening defined therein; and wherein the second connection portion comprises a second connection recess defined therein and a second opening defined therein.

3. The mounting apparatus of claim 2, wherein the first connection recess communicates with the second portion, and the second connection recess communicates with the second opening.

4. The mounting apparatus of claim 3, wherein a direction of the first opening and the second opening face away from each other.

5. The mounting apparatus of claim 1, wherein the first connection portion and the second connection portion are made of resilient material.

6. The mounting apparatus of claim 5, wherein the resilient material is rubber or silicone.

7. The mounting apparatus of claim 1, wherein the connection post comprises a third connection portion defined on a middle thereof, and wherein the connection post fixes to the second bracket by the third connection portion.

8. The mounting apparatus of claim 1, wherein the first bracket further comprises a first bottom plate and two first side plates extending up from two edges of the bottom plate; wherein the second bracket further comprises a second bottom plate and two second side plates extending up from two edges of the bottom plate.

9. The mounting apparatus of claim 8, wherein the first bracket and the second bracket are substantially U-shaped.

10. The mounting apparatus of claim 8, wherein a first fixed portion extends outward from an end of the first bottom plate, and wherein the comprises a recess defined therein.

11. The mounting apparatus of claim 10, wherein a second fixed portion extends outward from an end of the second bottom plate, and wherein the second fixed portion comprises a bar extending outward therefrom, and wherein upon the condition that the first bracket and the second bracket are placed in a front-to-back direction, the bar is received in the recess of the first bracket.

12. The mounting apparatus of claim 8, wherein the first connection portion extends from a right edge of the first bottom plate and away from the two first side plates; and wherein the second connection portion extends from a left edge of the first bottom plate and away from the two first side plates.
